(19) United States
(12) Patent Application Publication
(10) Pub. No.: US 2004/0266129 A1
(43) Pub. Date: Dec. 30, 2004

(54) METHOD OF FORMING SILICON-ON-INSULATOR WAFERS HAVING PROCESS RESISTANT APPLICATIONS

(75) Inventors: Joel P. DeSouza, Putnam Valley, NY (US); Harold J. Hovel, Katonah, NY (US); Junedong Lee, Hopewell Junction, NY (US); Siegfried L. Maurer, Stormville, NY (US); Devendra K. Sadana, Pleasantville, NY (US); Dominic Schepis, Wappingers Falls, NY (US); Ghavam Shahidi, Yorktown Heights, NY (US); Neena Garg, Fishkill, NY (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 10/604,146

(22) Filed: Jun. 27, 2003

(51) Int. Cl. H01L 21/76; H01L 21/425

(52) U.S. Cl. 438/407; 438/423; 438/528

(57) ABSTRACT

Disclosed herein is a method of providing improved electrical isolation in a separation by ion implanted oxide (SIMOX) process of making an SOI wafer. The method includes implanting ions into a substrate in a base dose implant conducted at a first energy level, implanting ions into the substrate at a second energy level in a second implant while the substrate is held at room temperature, and annealing the substrate to cause the implanted ions to be redistributed throughout the buried oxide (BOX) layer of the SOI wafer.

### BACKGROUND OF INVENTION

The invention relates to semiconductor manufacturing processes, and more particularly to a method of making a silicon-on-insulator wafer.

In fabricating integrated circuits in conventional bulk semiconductor wafers, wells of either P-type or N-type conductivity are implanted in a substrate of the opposite conductivity. However, in complementary metal oxide semiconductor (CMOS) technology, both p-type and n-type wells are utilized. Source/drain regions are formed by implanting diffusion regions of the opposite n-type or p-type conductivity as the wells to form metal-oxide-semiconductor field effect transistors (MOSFETs). In such integrated circuits, each transistor and/or other device must be electrically isolated from the others in order to work properly. Unfortunately, a relatively large amount of surface area is needed for the electrical isolation of the various transistors, which is in direct opposition with the current needs and goals of size reduction of these devices.

Another problem with current methods of providing electrical isolation is junction capacitance between source/drain regions and the bulk substrate. Such junction capacitance tends to increase power consumption and requires higher threshold voltages, which in turn affects the speed at which devices operate, and degrades frequency response.

In order to deal with the above-mentioned problems, silicon-on-technology (SOI) has been gaining popularity. SOI substrates have a structure in which an active device layer of single crystal silicon is formed over an insulating layer of the substrate. The insulating layer acts to eliminate capacitance between devices formed in the active device layer and the lower bulk layer of the substrate, and prevent the development of electrical paths through the substrate, which can ultimately degrade or destroy surface devices. Use of SOI substrates tends to decrease parasitic capacitance, leading to improvements in speed, reduced power consumption, better frequency response, and resistance to soft errors, while helping to address manufacturability concerns.

A number of methods are used in producing SOI substrates, the two more popular methods being bonding methods, and separation by ion implanted oxide (SIMOX). In bonding methods, a single crystal silicon wafer is bonded to another single crystal silicon wafer, the surface of which has been thermally oxidized, and then one of the silicon layers is converted to a uniform thin film by mechanical polishing or chemical etching. Bonding methods, however, can be costly and time-consuming, since two wafers are needed to produce one usable SOI wafer, and time-consuming polishing is required.

SIMOX is a preferred way of making SOI wafers, as it tends to be less costly than bonding methods. In a SIMOX process, accelerated high-energy oxygen ions are implanted into a single crystal silicon wafer or substrate. The oxygen ions come to rest at selected depths within the substrate in a Gaussian distribution pattern. The result is the formation of a region of implanted oxygen between an upper device layer and a lower bulk layer of the single crystal silicon substrate. The substrate is then annealed to react the implanted oxygen ions with the silicon to form a continuous buried oxide (BOX) layer of silicon dioxide below the upper device layer of the substrate, providing electrical isolation between the upper device layer and the bulk layer of the substrate.

Unfortunately, two problems are associated with SIMOX processes, which affect the dielectric strength of the BOX and its long-term reliability, as measured by its breakdown voltage. A first problem is the incomplete oxidation of the BOX layer that can occur in some SIMOX processes. Unoxidized regions of silicon atoms (Si) and incompletely oxidized silicon atoms (SiOₓ) may remain within the silicon dioxide (SiO₂) BOX layer after processing. Such regions tend to reduce the dielectric strength of the BOX layer and decrease its long-term reliability.

A second problem has arisen recently due to industry's current goal of making thinner upper device layers of SOI substrates, such upper device layers also being referred to as “SOI layers”. Thin BOX layers formed in substrates having thin SOI layers are more prone to damage during processing to form active devices in the SOI layer. Such processing can damage a thin BOX layer, making it more susceptible to dielectric breakdown.

However, making a thicker BOX layer is not desired because of greater costs and time requirements for processing. Nonetheless, when thicker BOX layers are used, certain plasma processes can cause charging of the SOI substrate between the SOI layer and the lower bulk layer, leading to charge breakdown, punching through weakened locations of the BOX, thus affecting device performance and increasing device defects. FIG. 1 illustrates the dielectric breakdown voltage of the BOX in relation to its thickness. As shown in FIG. 1, the breakdown voltage of the BOX is over 80 volts at full thickness for SIMOX wafers, but drops off rapidly with smaller thicknesses.

### SUMMARY OF INVENTION

According to an aspect of the invention, a method is provided for making SOI wafers having improved electrical isolation in the BOX layer. The method is used for making separation by ion implanted oxide (SIMOX) substrates. In the method, ions are implanted into the substrate in a base dose implant conducted at a first energy level. In a second implant conducted at a second energy level, ions are implanted while the substrate is held at room temperature. In an alternative embodiment, multiple base dose implants are performed, and a single RT implant is performed, and implants are performed at a plurality of different energy levels. Energy levels and ion implant doses are preferably reduced after initial implants are performed. Thereafter, annealing is performed to cause redistribution of ions within the substrate.

Alternatively, according to another aspect of the invention, a single base dose implant and multiple RT implants are performed, each implant being conducted at a different energy level. As before, energy levels and ion doses can be reduced in each subsequent implant. In yet another embodiment, multiple base dose implants and multiple RT implants are performed, each implant being conducted at a different energy level. Again, energy levels and ion doses can be reduced with each successive implant. Thereafter, annealing is performed to cause redistribution of ions within the substrate.

### BRIEF DESCRIPTION OF DRAWINGS

FIG. 1 is a graph showing degraded BOX properties;

FIG. 2 is a diagram illustrating a SIMOX implantation process to form an SOI wafer;

FIG. 3 is a flowchart showing an embodiment of the invention.

FIG. 4 is a flowchart showing an embodiment of the invention where multiple base dose implantations are used;

FIG. 5 is a flowchart showing an embodiment of the invention where multiple room temperature implantations are used;

FIG. 6 is a graphical illustration of Si inclusion density, with and without processing according to an embodiment of the invention;

FIG. 7 is a graphical illustration showing surface smoothness of an SOI layer;

FIG. 8 provides a graphical illustration of the BOX breakdown voltage for an improved BOX process; and

FIG. 9 is a graphical illustration showing the BOX breakdown voltage for various thicknesses of the BOX layer.

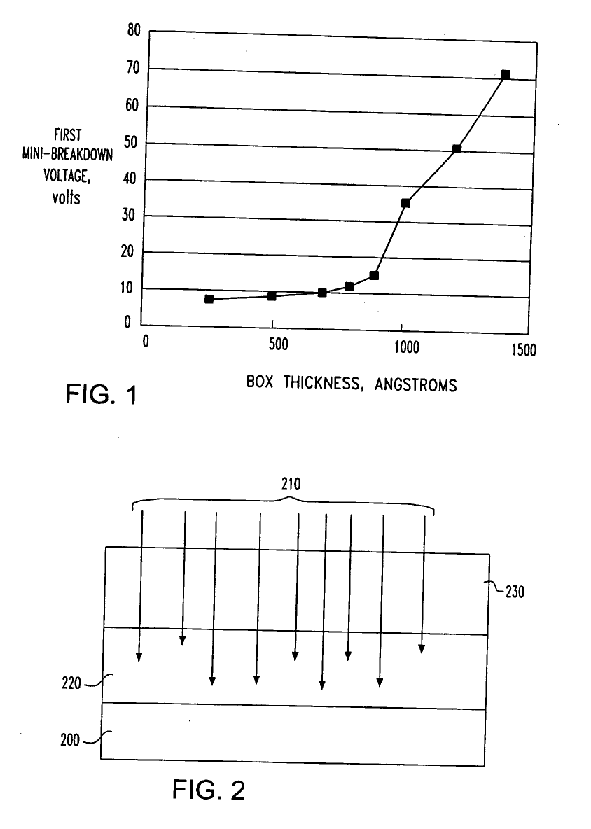

### DETAILED DESCRIPTION

In FIG. 2, a single crystal silicon substrate 200 is shown. A buried region 220 is implanted with oxygen ions 210 using an accelerated high-energy oxygen ion beam. This process is known as the first or base dose implant. For illustrative purposes, the SIMOX process is optimized for a nominal silicon-on-insulator layer 230 thickness of between 550 Ã□ to 700 Ã□ and a nominal BOX thickness of approximately 1350 Ã□ to 1550 Ã□. The implant dose is preferably in the range of 1×10¹⁶ to 4×10¹⁷ ions/cm². The oxygen ion implantation energy is preferably between 40 and 240 KeV. The substrate temperature is kept at about 200° C. to 600° C. during this base dose implant step.

A second implantation of oxygen ions is performed subsequent to the first implant step. During this second implant, the temperature of the substrate is maintained at room temperature (between 10 Â° C. and 25 Â° C.), such that the second implantation process is called a room temperature (RT) implant. The RT implant of oxygen may be carried out at a lower dose ranging between 5×10¹⁴ to 1×10¹⁶ ions/cm², but at the same energy as the base dose. The RT implant acts to amorphize the silicon layer at the depth determined by the energy level. The amorphized layer helps form a continuous BOX layer 220 and enhances internal thermal oxidation (ITOX) during the high temperature anneal that follows. This leads to a BOX layer 220 which has excellent properties when produced.

A variety of different ions can be used during this second implant step. For example, at times nitrogen ions can be used to passivate the trapped charge which results from broken silicon and oxygen bonds. Nitrogen reacts with free electrons and broken molecules to form stable bonds. However, since active devices are degraded by the presence of nitrogen, nitrogen is not always a good choice for the second implant.

An annealing step is then performed to redistribute the oxygen ions within the silicon substrate. Annealing tends to sharpen the demarcation between the buried silicon dioxide layer and the silicon layers, that is initially somewhat spread out because the implanted oxygen ions come to rest at different depths in a Gaussian distribution pattern within the substrate. During annealing, the substrate is held at temperature ranging between 1000 and 1400 degrees Celsius for a period of 6 to 10 hours.

Several embodiments of the invention incorporate internal oxidation to improve the dielectric properties of the oxide, not just at the surface, as in conventional SIMOX processes, but throughout the BOX layer, especially in the middle of the BOX layer where such areas are likely to be damaged by subsequent processing.

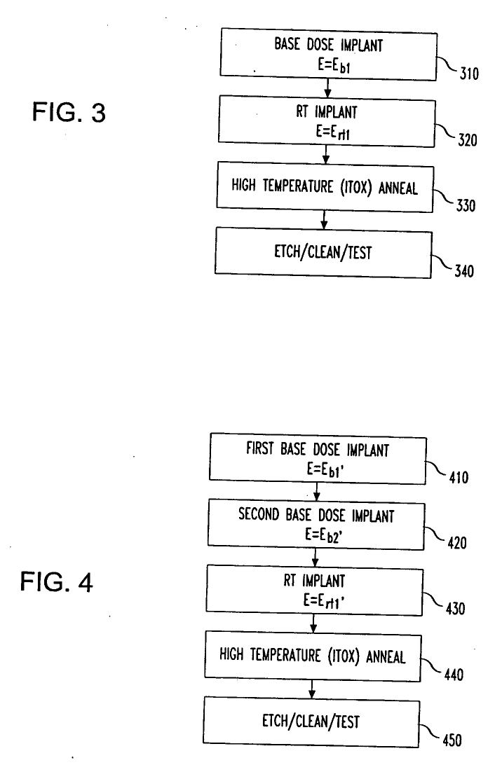

An embodiment of the invention is illustrated in FIG. 3. Whereas in conventional SIMOX processing, all implants are performed at the same energy, in the embodiments shown in FIGS. 3 through 5, each implant is performed a different energy level than other implants. The combination of dose and energy levels in each implant, and the offset between each implant are key for performing an improved SIMOX process according to the invention.

In FIG. 3, a SIMOX process is provided to produce a high voltage breakdown BOX. In this embodiment, implant energy is offset between the base dose and the RT implant. This technique is preferred for forming a relatively thin BOX region of about 1200 Ã□ or less, using a relatively low oxygen dose of about 2×10¹⁷ ions/cm² or less. Because of the simplicity of the process, this is also one of the most cost-effective ways of making high quality BOX layers.

The first step in the process is the base dose implant 310, as shown in FIG. 3, which is performed at a first energy level E_{b1}. The next processing step is the RT implant 320, performed at a second energy level Eᵣₜ₁. Eᵣₜ₁ is preferably lower than E_{b1} in value. Performing the RT implant at a lower energy than the base dose implant results in a tighter distribution of oxide precipitates during the high temperature annealing process 330 which follows. This, in turn, reduces the amount of silicon (Si) inclusions in the BOX during the internal oxidation step. Thereafter, post-processing etch, cleaning and testing procedures may be selectively conducted to ensure device performance, as shown at 340.

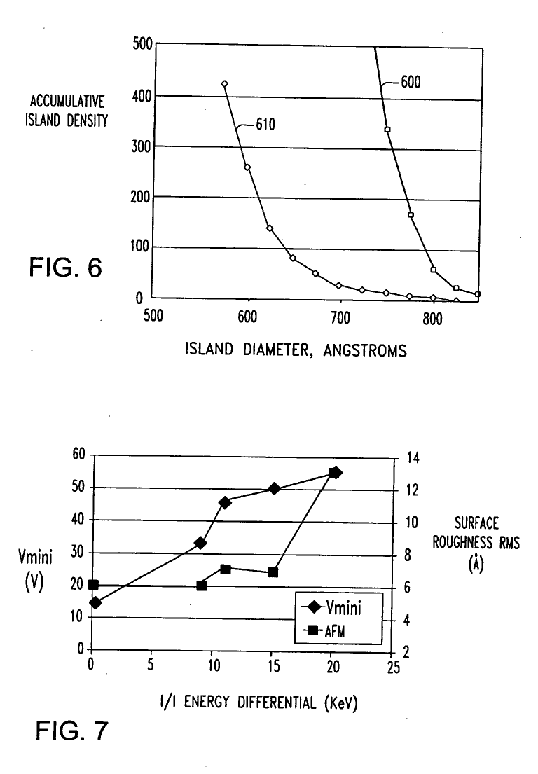

FIG. 6 graphically illustrates Si island inclusion density in the BOX from conventional SIMOX as shown at the curve 600 and the improved SIMOX as per one embodiment of the present invention, as shown at curve 610. The reduction of the inclusion size and density in the improved SIMOX clearly contributes to the improved breakdown voltage of the material.

It is important to determine the differential between the base dose energy and the RT implant energy. If the differential is excessive, it can degrade the surface smoothness of the SOI layer, as shown in FIG. 7. A preferred differential between base and RT implants is calculated to be about 10% or less of the base dose energy.

An illustrative example can now be used to further demonstrate the improved SIMOX process as provided by the present invention. In this example, a process sequence is used to produce an SOI substrate with a nominal Si thickness of 700 Ã□ and a high voltage BOX thickness of about 1350 Ã□ Starting with a bulk silicon substrate, a base dose oxygen implant is first performed. In this illustrative example, the dosage for this implant is at 2.5×10¹⁷ ions/cm². The base dose implant is conducted at an energy E_{b1} of 180 KeV. The wafer temperature is kept at 365Â° C.

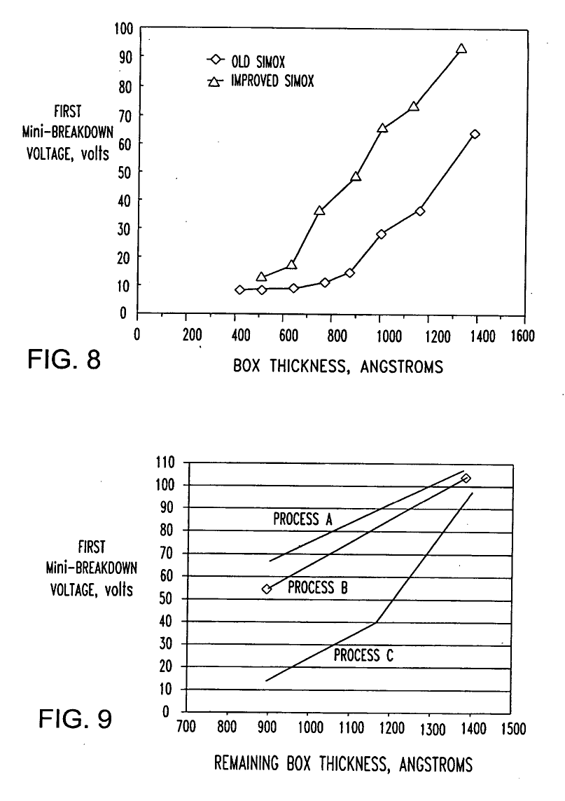

A room temperature implant is then conducted. The dosage for the RT implant in the illustrative example is at 2.0×10¹⁵ ions/cm². The RT implant is conducted at an energy level Eᵣₜ₁ which is at 165 KeV. Eᵣₜ₁ is therefore lower than E_{b1} in this example by about 8 percent An anneal is then conducted at a temperature of 1320 degrees Celsius for a total of 15 hours with an Argon ambient having between about 4% and 45% oxygen. After the anneal, a BOX layer having increased breakdown voltage results. A graph of the BOX breakdown voltage for the improved BOX process is shown in FIG. 8.

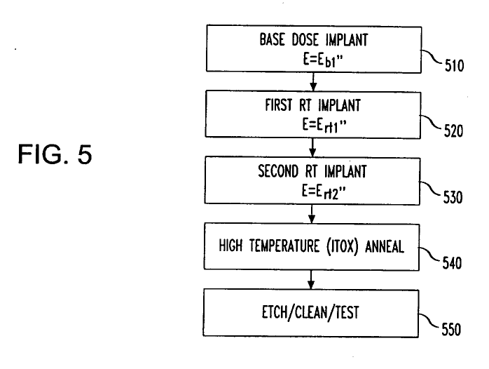

The base dose implant can be performed either as a single step or in multiple steps. The total dose, however, for all base dose implants preferably ranges between 1×10¹⁶ and 4×10¹⁷ ions/cm² at a preferred energy between about 40 KeV and 240 KeV. The RT dose implant also can be done in single or in multiple steps to a total dose ranging between 5×10¹⁴ to 1×10¹⁶ ions/cm², at an energy between 10% and 20% lower than the base dose implant. Alternative embodiments of the present invention having multiple base implants and RT dose implants are described relative to FIGS. 4 and 5 below.

In FIG. 4, an alternative embodiment of the present invention is provided having multiple base dose implants. In this embodiment, only a single RT implantation process is shown. Multiple base dose implants are preferred in situations where a high quality BOX layer is desired. The thickness of the BOX layer in such situations is usually greater than 1200 Ã□. It is also preferable to use an oxygen dose of 2×10¹⁷ ions/cm² or higher to achieve better results.

The first base dose implant, as shown at 410, is performed at a first energy level E_{b1}′. A second base dose implant 420 is then performed at a different energy level E_{b2}′. It is preferable that the second energy level E_{b2}′ be lower than the first energy level E_{b1}′. In a preferred embodiment, the value of E_{b2}′ is 5 to 10 percent lower than the value of E_{b1}′. It should be noted that although, for illustrative purposes, only two base implantation processes are discussed in the illustrative example of FIG. 4, it is possible to utilize many base dose implants, each with different energy levels E_{b1}′ to E_{bn}′, where n is the total number of implantation steps for base dose implants. Preferably, each subsequent implant step is conducted at a lower energy level than the step before it.

It should be noted that incorporating wafer cleaning techniques between implant steps results in reduced density of BOX shorts and blocked implant defects, in addition to improved breakdown voltage. Furthermore, the BOX layer is usually formed at the location defined by the last (or the second, in case of FIG. 4) base dose implant and the subsequent RT implant steps.

The first (or early) base dose implant(s) at higher energy provides additional oxygen to the BOX forming at shallower region during the high temperature anneal, which enhance the ITOX process of the BOX. This improves the breakdown voltage of the BOX even further.

After the base dose implanting is completed, a single RT dose implant process 430 is conducted at an energy level of Eᵣₜ₁′ which is a different energy level than either E_{b1}′ or E_{b2}′ in the example shown in FIG. 4. It is preferable for the value of Eᵣₜ1′ to be lower than all the base dose energy levels. The preferred energy differential between the second base dose implant, and the RT implant is about 10% or less of the second base implant energy E_{b2}′. The preferred differential between the two base implant energies is about 20% or less of the first base implant energy E_{b1}′. After the RT implant, a high temperature anneal 440 is performed, which is preferably followed by post-processing etching, cleaning and testing, as shown at 450.

A third embodiment is shown in FIG. 5. In FIG. 5, multiple RT implants are performed, but only with a single base dose implant. This embodiment is preferable in situations where the formation of a BOX layer having a thickness of 1600 Ã□ or greater is desired, needing an improved breakdown voltage. This is because the additional damage done by the RT implant will enhance the amount of internal oxidation (ITOX) during high temperature annealing and therefore provide a higher quality oxide in the BOX. Moving the location of the RT implant with respect to the base implant can also lead to a thicker BOX as well, which may be even more desirable to prevent post-SIMOX damage to the BOX.

As shown in FIG. 5, the base dose implant step 510 is conducted at an energy level E_{b1}″. The base dose implant step is followed by a first RT implant step 520 which is conducted at a different energy Eᵣₜ₁″. Eᵣₜ₁″ is preferably lower than the base dose implant energy. In an embodiment, the difference between the base dose implant energy and the first RT implant energy is 5 to 10 percent. A second RT implant step 530 is then conducted at an energy level Eᵣₜ₂″ which is different from both the base dose energy E_{b1}″ and the second RT energy Eᵣₜ₁″. In a preferred embodiment, Eᵣₜ₂″ is lower than Eᵣₜ₁″, preferably by 5 to 10 percent.

Again, as in the case of the previous embodiment, even though in this illustrative example only two RT dose implant processes are utilized, it is possible to use many RT implants, each having a different energy level Eᵣₜ₁″ to Eᵣₜₘ″ where “m” represents the number of RT processes. In a preferred embodiment, each subsequent energy level has a value that is lower than the base dose implant energy E_{b1}″, as well as the RT energy level preceding it. A high temperature annealing process is then conducted at 540, followed by a selective etching/cleaning/testing process 550 to test for performance and provide a desired surface.

It should be noted that although the embodiments of FIGS. 4 and 5 each provide implantations involving multiple base dose implants and a single RT dose implant, or alternatively, a single base dose implant and multiple RT dose implants, it is possible to combine the two situations as to provide multiple base dose implants with multiple RT dose implants, each implant preferably having a distinct energy level that is preferably lower than the energy level of the preceding implant, as discussed above.

In either case, the embodiments of the present invention, through various combinations of multiple base dose implants at varying energies, followed by precise offset in energies for the RT implants above and or below the BOX, can lead to a BOX having an improved breakdown voltage, with more processing capability, which is more charging resistant than conventional SIMOX processes. This same concept is reflected in FIG. 9 below.

FIG. 9 is a graph illustrating a relationship between the BOX breakdown voltage versus BOX thickness for various processes. It should be noted that while other SIMOX processes outside the scope this application may provide ways to produce an initial improvement in the BOX breakdown voltage, it is the strength of the BOX after it is thinned during subsequent processing that is most important. Furthermore, the graph of FIG. 9 shows differing thinned BOX breakdown results (processes A, B and C), which indicates that different slopes exist between the initial BOX breakdown voltage and thinned BOX breakdown voltage. Consequently, it does not follow that any SIMOX process, when measured at initial full thickness before other processing, can predict results for a BOX layer thinned by subsequent processing that are acceptable except for the improved specific combinations that are provided by the present invention.

While the invention has been described in accordance with certain preferred embodiments thereof, those skilled in the art will understand the many modifications and enhancements which can be made thereto without departing from the true scope and spirit of the invention, which is limited only by the claims appended below.

1. A method of providing electrical isolation in a separation by ion implanted oxide (SIMOX) substrate, comprising:
implanting ions into a substrate in a base dose implant conducted at a first energy level;
implanting ions into said substrate at a second energy level in a second implant while said substrate is held at room temperature; and
annealing said implanted substrate to cause said ions to be redistributed in said substrate.

2. The method of claim 1 wherein said substrate comprises single crystal silicon.

3. The method of claim 1, wherein said implanted ions comprise oxygen ions.

4. The method of claim 1, wherein said second energy level is lower than said first energy level.

5. The method of claim 2, wherein said implanted ions comprise oxygen ions.

6. The method of claim 5, wherein said implanting and said annealing result in formation of a continuous buried oxide (BOX) layer which provides electrical isolation for a silicon-on-insulator layer of said substrate.

7. The method of claim 1, wherein said first and said second energy levels are in the range of 40 to 240 KeV.

8. The method of claim 1, wherein a lower dosage of ions are implanted in said second implant than in said base dose implant.

9. A method of providing electrical isolation in a separation by ion implanted oxide (SIMOX) substrate, comprising:
implanting ions into a substrate in a plurality of base dose implants conducted at a plurality of different energy levels;
implanting ions into said substrate in a second implant at a second energy level while maintaining said substrate at room temperature; and
annealing said implanted substrate to cause said ions to be redistributed in said substrate.

10. The method of claim 9, wherein each of said base dose implants is conducted at a lower energy level than the implant which precedes it.

11. The method of claim 10, wherein said second energy level used in said second implant is lower than any of said energy levels used in said base dose implants.

12. The method of claim 9, wherein said cumulative implant dose from all said base dose implants is in the range of 1×10¹⁶ to 4×10¹⁷ ions/cm².

13. The method of claim 9, wherein a plurality of said second implants are conducted each at a different energy level that is also different than said energy levels at which said plurality of base dose implants are conducted.

14. The method of claim 13, wherein each said implant is conducted at a lower energy level than any of said implants preceding it, such that said second implants are conducted at energy levels lower than any of said base dose implants.

15. The method of claim 13, wherein said plurality of said second implants provide a total accumulated ion implant dosage that is lower in value than a total accumulated ion implant dosage provided by said plurality of base dose implants.

16. A method of providing electrical isolation in a separation by ion implanted oxide (SIMOX) substrate, comprising:
implanting ions into a substrate in a base dose implant conducted at a first energy level;
implanting ions into said substrate in a plurality of subsequent implants during which said substrate is held at room temperature, each of said plurality of subsequent implants being conducted at a separate energy level; and
annealing said implanted substrate to cause said ions to be redistributed in said substrate.

17. The method of claim 16, wherein each of said subsequent implants is conducted at a lower energy level than the implant preceding it.

18. The method of claim 17, wherein said first energy level at which said base dose implant is conducted is higher than any of said energy levels at which said subsequent implants are conducted.

19. The method of claim 17, further comprising cleaning a surface of said substrate between each said implant.

20. The method of claim 16, wherein a plurality of said base dose implants are conducted each at a different energy level that is also different than said energy levels at which said plurality of said subsequent implants are conducted.
